(19) United States
(12) Patent Application Publication
(10) Pub. No.: US 2023/0260871 A1
(43) Pub. Date: Aug. 17, 2023

(54) Three-Dimensional Device Package with Vertical Heat Pipes

(71) Applicant: MARVELL ASIA PTE LTD, Singapore (SG)

(72) Inventors: Janak G. Patel, South Burlington, VT (US); Richard S. Graf, Gray, ME (US); Manish Nayini, Wappingers Falls, NY (US)

(21) Appl. No.: 18/167,912

(22) Filed: Feb. 13, 2023

Related U.S. Application Data
(60) Provisional application No. 63/309,743, filed on Feb. 14, 2022.

(51) Int. Cl. H01L 23/427; H01L 25/065; H01L 23/00

(52) U.S. Cl. CPC H01L 23/427; H01L 25/0652; H01L 24/32; H01L 2225/06513; H01L 2225/06517; H01L 2224/16145; H01L 2224/16225; H01L 2224/32155; H01L 2924/16235; H01L 24/16

(57) ABSTRACT

An electronic device includes a substrate, and a stack of dies stacked on the substrate. The stack includes (i) multiple dies stacked on one another, the multiple dies include electronic components and interconnections, and (ii) one or more heat pipes (HPs), which are traversing at least a subset of the dies at a right angle relative to the substrate, at least one of the HPs being configured to dissipate heat generated by operation of the electronic components away from at least the subset of the dies.

### CROSS-REFERENCE TO RELATED APPLICATIONS

This application claims the benefit of U.S. Provisional Patent Application 63/309,743, filed Feb. 14, 2022, whose disclosure is incorporated herein by reference.

### FIELD OF THE DISCLOSURE

The present invention relates generally to electronic devices, and particularly to methods and systems for improving heat dissipation in a three-dimensional (3D) package of stacked integrated circuits (ICs).

### BACKGROUND

Various techniques are known in the art for stacking multiple ICs in electronic devices and dissipating heat therefrom.

The description above is presented as a general overview of related art in this field and should not be construed as an admission that any of the information it contains constitutes prior art against the present patent application.

### SUMMARY

An embodiment that is described herein provides an electronic device, including a substrate and a stack of dies stacked on the substrate. The stack includes (i) multiple dies stacked on one another, the multiple dies including electronic components and interconnections, and (ii) one or more heat pipes (HPs), which are traversing at least a subset of the dies at a right angle relative to the substrate, at least one of the HPs being configured to dissipate heat generated by operation of the electronic components away from at least the subset of the dies.

In some embodiments, at least one of the HPs contains a fluid, and at least the one of the HPs being configured to move the fluid within the HP for dissipating the heat. In other embodiments, the HP includes: (i) an inner wall defining a first channel, (ii) an outer wall surrounding the inner wall and defining a second channel between the inner wall and outer wall, and (iii) one or more first openings in the inner wall for transferring the fluid between the first channel and second channel. In yet other embodiments, the multiple dies include (i) a first die being an outer die of the stack, and (ii) a second die disposed on the substrate, and at least one of the HPs traverses at least the first die.

In some embodiments, the stack includes a third die disposed between the first die and the second die, and the HPs include: (i) a first HP traversing the first die and the third die but not traversing the second die, and (ii) a second HP traversing the first die, the third die and the second die. In other embodiments, the first die has a first surface being an outer surface of the stack of dies, and the electronic device includes a heat dissipation element disposed over the first surface and having a second surface opposite the first surface of the first die, the heat dissipation element being configured to dissipate the heat from at least one of the dies. In yet other embodiments, the heat dissipation element has a second opening, and at least one of the HPs is configured to traverse at least part of the second opening along the heat dissipation element.

In some embodiments, a third surface of the outer wall of at least one of the HPs, is flush with the second surface of the heat dissipation element. In other embodiments, the electronic device includes: (i) a hole traversing at least the subset of the dies, the hole being configured to contain a given HP of the HPs, and (ii) a layer formed between the given HP and a wall of the hole, the layer includes thermally conductive material (TCM) configured to transfer the heat between the subset of the dies and the given HP. In yet other embodiments, at least one of the HPs being disposed at a region identified as a hot spot in at least one of the dies.

There is additionally provided, in accordance with an embodiment of the present invention, a method for producing an electronic device, the method including disposing on a substrate a stack of dies, the stack including multiple dies stacked on one another, the multiple dies including electronic components and interconnections, and fabricating in the stack one or more heat pipes (HPs), which are traversing at least a subset of the dies at a right angle relative to the substrate, at least one of the HPs used for dissipating heat, which is generated by operation of the electronic components, away from at least the subset of the dies.

The present disclosure will be more fully understood from the following detailed description of the embodiments thereof, taken together with the drawings in which:

### BRIEF DESCRIPTION OF THE DRAWINGS

FIG. 1 is a schematic, sectional view of an electronic device, in accordance with an embodiment that is described herein;

FIG. 2 is a schematic, sectional view of an electronic device, in accordance with another embodiment that is described herein;

FIG. 3 is a schematic, sectional view of the electronic device of FIG. 1, in accordance with an embodiment that is described herein;

FIGS. 4-7 are schematic, top views of the electronic device of FIG. 2, in accordance with embodiments that are described herein;

FIG. 8 is a schematic, sectional view of an electronic device, in accordance with another embodiment that is described herein;

FIG. 9 is a schematic, sectional view of an electronic device, in accordance with another embodiment that is described herein;

FIG. 10 is a flow chart that schematically illustrates a method for producing the electronic device of FIG. 9, in accordance with an embodiment that is described herein; and

FIG. 11 is a schematic, sectional view of a jig used for producing heat pipes of the electronic device of FIG. 9, in accordance with an embodiment that is described herein.

### DETAILED DESCRIPTION OF EMBODIMENTS

Electronic devices may comprise multiple dies stacked together over a substrate in a three-dimensional (3D) package. The dies are typically formed on a semiconductor (e.g., silicon) substrate, the dies comprise electronic components and interconnections, and are configured to exchange electrical signals with the substrate, and in some cases, with one another.

The number and type of dies of such 3D packages depend on the application of the electronic device. While being operated, the electrical current flowing through the electronic components of each die, induce heat produced by the respective die.

The stack of dies is typically confined between: (i) the substrate, which is typically made from a polymer matrix and has low thermal conductivity, and (ii) a lid or any other suitable element, which is typically made from a suitable metal (e.g., copper) and has high thermal conductivity. In this configuration, the package is configured to dissipate most of the heat through the lid. Thus, the heat produced by the dies disposed between the substrate and the uppermost die of the stack, is confined within the package, and therefore, increases the temperature of the electronic device. The increased temperature may impair the functionality and/or reliability of the electronic device.

Embodiments of the present disclosure that are described herein, provide techniques for improving the heat dissipation from a 3D package of an electronic device using one or more heat pipes (HPs) formed (e.g., embedded) within the structure of the stack.

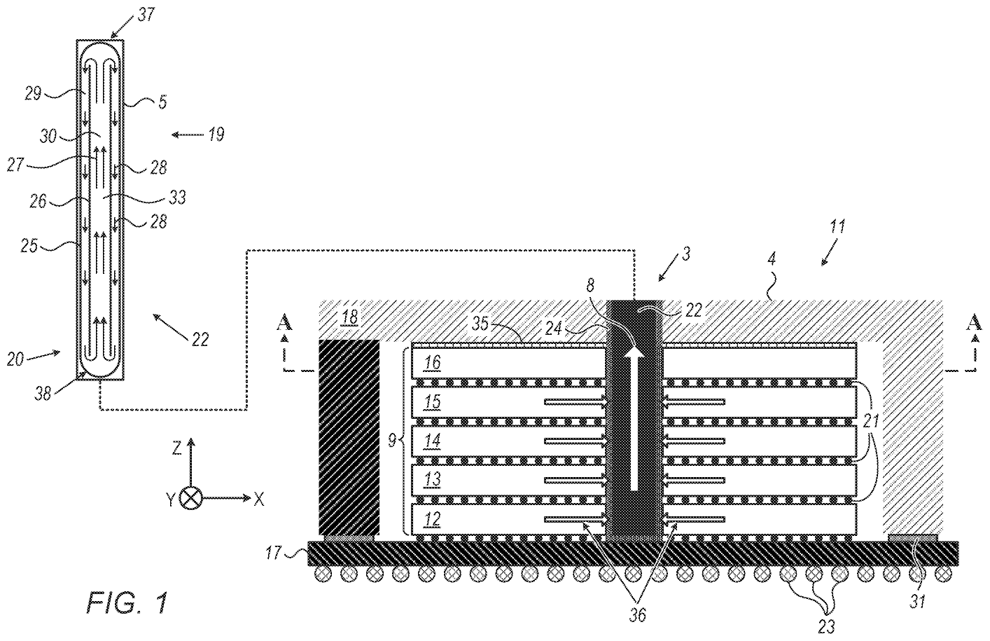

In some embodiments, the electronic device comprises (i) a substrate whose properties are described in detail with reference to FIG. 1 below, and (ii) a stack of dies stacked on the substrate, each of the stacked dies comprising electronic components and interconnections. The stack has one or more holes traversing at least a subset of the stacked dies at a right angle relative to the substrate. Therefore, a longitudinal axis of the holes is orthogonal to the surface of the substrate. During the operation of the electronic device, the electronic components of the dies generate heat due to electrical current flowing therethrough.

In some embodiments, each traversing hole contains a heat pipe (HP), which is configured to dissipate the generated heat away from at least the subset of the stacked dies. The HP comprises: (i) an inner wall defining a first channel, (ii) an outer wall surrounding the inner wall and defining a second channel between the inner and outer walls, and (iii) one or more openings in the inner wall for transferring fluid between the first and second channels. In some embodiments, the fluid comprises water or any other suitable fluid configured to flow through the channels of the HP, so as to dissipate the heat away from the electronic device.

In some embodiments, a layer of thermally conductive material (TCM) is disposed along the hole, between the HP and a wall of the hole. The TCM layer is configured to transfer the heat from the subset of the dies to the HP. Embodiments related to the structure and properties of the hole, the HP, and the TCM layer, are described in detail in FIGS. 1-9 below.

Some of the stacked dies may have one or more regions identified as hot spots in the respective dies. The region may be identified using: (i) simulations in the design phase of each die of the stack, and the design of the 3D package, and (ii) empirical data obtained while performing functional and/or reliability testing of each individual device, and of the 3D package. The term hot spot refers to a region in the die having a temperature that exceeds a temperature threshold during operation of the respective die. In some embodiments, at least one of the HPs is formed in close proximity to, or at the hot spot of at least one of the dies. It is noted that in order to incorporate the one or more HPs in the stack, the design of the at least one of the stacked dies must allocate a keep-out zone, which does not have any functional electronic component.

In some embodiments, the stack may comprise at least three stacked dies, referred to herein as first, second and third dies. The first die is the uppermost die, also referred to herein as an outer die of the stack, the second die is disposed over the substrate, and the third die is disposed between the first and second dies. In some embodiments, the stack comprises (i) a first HP traversing the first die and the third die, but not traversing the second die, and (ii) a second HP traversing the first die, the third die and the second die. In such embodiments, the first HP is configured to dissipate heat from the first and third dies, whereas the second HP is configured to dissipate heat from all three dies of the stack. It is noted that heat pipes inserted at different die levels in the stack can enable the required dissipation of heat from the stack, while reducing the number of keep-out zones. The reduced number of keep-out zones typically increases the number of electronic components in one or more of the respective dies, and thereby, may increase the functionality of the electronic device.

In some embodiments, the 3D package comprises a heat dissipation element, such as a lid and/or a heat sink, which may be disposed over the outer die of the stack. In some embodiments, at least one of the holes also traverses the dissipation element and is filled with the HP and the TCM layer as described above. In some embodiments, the outer surfaces of the HP and TCM layer may be flush with an outer surface of the heat dissipation element, so as to increase the rate of heat dissipation from the stack of the electronic device. Additional embodiments and variations of the techniques described above, including a method for producing the HP in the stack, are described in detail in FIGS. 1-11 below.

The description above is presented as a general overview of embodiments of the present disclosure, which are described in detail herein.

FIG. 1 is a schematic, sectional view of an electronic device 11, in accordance with an embodiment that is described herein.

In some embodiments, electronic device 11, also referred to herein as device 11 for brevity, comprises a substrate 17, and a stack 9 of dies 12, 13, 14, 15 and 16, stacked on substrate 17 and described in detail below.

In some embodiments, substrate 17 comprises a suitable polymer or ceramic substrate and metal traces (not shown) patterned in the substrate. In the present example, substrate 17 comprises Ajinomoto Build-up Film® (ABF) laminate GL-102 produced by Ajinomoto Fine-Techno Co. Inc. (Kawasaki-shi, 210-0801, Japan), or any other suitable package substrate, and the metal traces comprise copper or aluminum or any suitable alloy thereof, which are produced using any suitable processing techniques of circuit boards and integrated circuit (IC) substrates. In some embodiments, substrate 17 has a thickness between about 0.4 mm and 3 mm along a Z-axis of an XYZ coordinate system.

In the context of the present disclosure and in the claims, the terms “about” or “approximately” for any numerical values or ranges indicate a suitable dimensional tolerance that allows the part or collection of components to function for its intended purpose as described herein.

In some embodiments, device 11 comprises solder balls 23 of a ball grid array (BGA) that are formed between substrate 17 and one or more additional substrates (not shown) and are configured to serve as terminals and to conduct electrical signals between substrates 17 and the one or more additional substrates.

In other embodiments, instead of balls 23, device 11 may comprise pads of a land grid array (LGA), and the one or more additional substrates may have suitable pins aligned with the pads for exchanging signals therebetween. Alternatively, instead of balls 23, device 11 may comprise pins of a pin grid (PGA), and the one or more additional substrates may have one or more respective sockets with holes configured to fit over the pins of device 11 for exchanging signals between device 11 and the one or more additional substrates.

In some embodiments, stack 9 comprises multiple dies, in the present example five dies 12-16. Each of dies 12-16 comprises a semiconductor substrate (e.g., silicon, germanium, gallium arsenide) and electronic components and interconnections implemented in electronic circuits of each die (not shown).

In some embodiments, each of dies 12-16 comprise one or more through-silicon vias (TSVs) (not shown) configured for conducting electrical signals therethrough, at least along the Z-axis. In an embodiment, at least one of the TSVs may be connected to ground, and the other TSVs may conduct power signals and data signals between a pair of adjacent dies among dies 12-16, and/or between one of dies 12-16 and substrate 17.

In some embodiments, stack 9 comprises terminals, in the present example, bumps 21, which are formed between every pair of dies 12-16 of stack 9, and also between die 12 and substrate 17. Bumps 21 are configured to conduct the electrical signals between every adjacent pair of the dies 12-16 of stack 9, and between die 12 and substrate 17.

In some embodiments, each of the TSVs is formed between a respective pair of bumps 21 located along the Z-axis above and below the respective TSV. In other embodiments, two or more of the TSVs may be connected to a single bump 21, e.g., via a redistribution layer (RDL) and/or via large pads (both not shown). Additionally, or alternatively, two or more bumps 21 may be routed to a single TSV (e.g., via the aforementioned RDLs).

Additionally, or alternatively, one or more bumps 21 may be disconnected from the TSVs and may be formed for other purposes, for example, to maintain flatness of one or more of dies 12-16 of stack 9, which affects the reliability of electronic device 11.

In the present example, all the TSVs may be similar in all dies 12-16. In other embodiments, at least one pair of dies among dies 12-16 may have different TSVs, based on the electronic specifications and the application of each die. Moreover, the number of TSVs may differ between the pairs of dies. For example, dies 12-16 may comprise a processing die and a memory die, each of which may have a different number of input and output terminals, and therefore, a different number of TSVs compared to the other die.

In some embodiments, device 11 comprises a lid 18, which typically surrounds dies 12-16, and is configured to encapsulate stack 9 of dies 12-16. In the present example, lid 18 is typically made from a suitable metal (e.g., nickel-plated copper) having a thickness (e.g., along the Z-axis) between about 0.3 mm and 3 mm. The metal-based lid 18 has high thermal conductivity, for example, the thermal conductivity of nickel is about 97 W/mK and the thermal conductivity of copper is about 398 W/mK.

In the present example, the thickness of the plated nickel is about a few micro-inches (e.g., between about 0.0025 mm and 0.025 mm), thus, the nickel-plated copper of lid 18 may have a thermal conductivity larger than about 390 W/mK. Note that the thickness ratio between the nickel and the copper, and the properties of the coating (which depends on the coating process) typically determine the thermal conductivity of lid 18.

In some embodiments, device 11 comprises a thermal interface material (TIM) layer 35, disposed between die 16 and lid 18. In the present example, TIM layer 35 comprises a soft thermal conductive gel product X23-7772-4 supplied by Shin-Etsu MicroSi Inc. (10028 S. 51st Street Phoenix, Ariz. 85044), and having a thickness between about 20 μm and 150 μm.

In some embodiments, TIM layer 35 is formed over the surface of die 16 (or over a suitable passivation layer formed over the outer surface of die 16), and is configured to conduct heat from die 16 to lid 18. Note that in the present example, the heat is typically generated during the operation of the electronic components of die 16 (and one or more of dies 12-15), as will be described in detail below.

In some embodiments, lid 18, which is formed using a stamping process (or any other suitable process), is assembled over: (i) TIM layer 35 formed over the surface of die 16, and (ii) a suitable adhesive layer 31 formed over the surface of substrate 17, for encapsulating stack 9. In the present example, adhesive layer 31 comprises epoxy SE4450 produced by DuPont (Wilmington, Del.) having a thickness between about 50 μm and 200 μm.

In some embodiments, dies 12-16 are configured to exchange electrical signals with substrate 17, and typically but not necessarily, also with one another. While being operated, the electrical current flowing through the electronic circuits of at least one of dies 12-16, induces heat produced by the respective die(s) 12-16. It is noted that at least one of (and typically both) TIM layer 35 and lid 18 may serve as heat dissipation elements, such that die 16, which is the outer die of stack 9, is typically being cooled by TIM layer 35 and lid 18. However, dies 12-15 are positioned between substrate 17 and die 16, and therefore, produce heat that must be dissipated in order to prevent overheating of stack 9, and thereby, enable the operation of device 11.

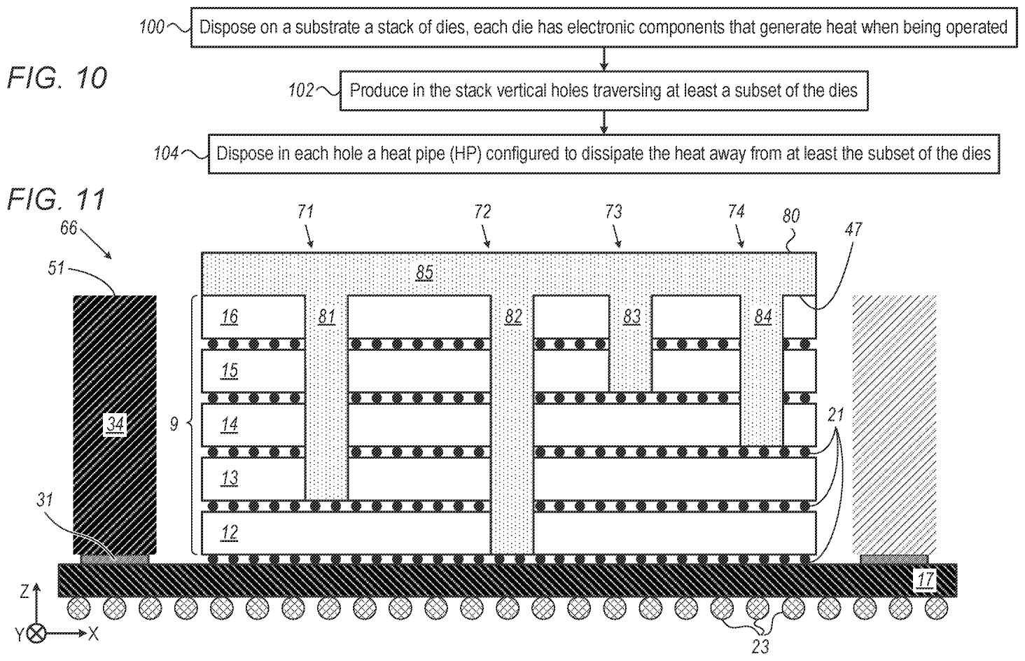

In some embodiments, stack 9 comprises one or more heat pipes (HPs) 22 contained in one or more respective holes 3 traversing at least a subset of dies 12-16. In the present example, stack 9 comprises a single HP 22, which is traversing (e.g., formed through) dies 12-16 at a predefined angle, typically a right angle, relative to substrate 17. In such embodiments, at least a section of the heat pipe is orthogonal to substrate 17, and is also referred to herein as a vertical heat pipe (VHP). In the example of device 11, hole 3 is traversing: (i) lid 18, (ii) TIM layer 35, and (iii) each of dies 12-16 and between dies 12-16, using any suitable technique (such as, but not limited to etching or laser drilling, as will be described in more detail in FIG. 10 below).

Subsequently, a layer of a thermally conductive material (TCM) 24 having a thickness between about 50 μm and 200 μm, is disposed along the Z-axis, over the walls of hole 3, and HP 22 is formed within the respective hole 3 and surrounded by TCM 24. It is noted that in the example of device 11, hole 3 has contiguous walls extended between a surface 4 of lid 18 and the surface of substrate 17, whereas the aforementioned TSVs are formed along the Z-axis through each individual die (among dies 12-16), and bumps 21 is buffered between each pair of dies 12-16.

In the present example, hole 3 has a round-shaped cross section in an XY plane, with any suitable diameter between about 2 mm and 20 mm. In other embodiments, instead of a round shape, hole 3 may have any other suitable shape, such as but not limited to an ellipse, a square, or a rectangle. In such embodiments, device 11 may comprise a trench instead of hole 3.

In some embodiments, in order to incorporate hole 3, TCM 24 and HP 22, the design of dies 12-16 must allocate a keep-out zone (shown for example in FIGS. 6 and 7 below). Note that the keep-out zone does not have any functional electronic component, such as transistors and/or memory cells, at least at the location of hole 3, TCM 24 and HP 22. Moreover, it is noted that excluding functional device elements may reduce some functionality (e.g., processing power or memory capacity) from device 11, but each HP 22 improves the heat dissipation from device 11, and therefore, may improve the overall functionality of the respective dies, and of stack 9. In some embodiments, other components of device 11, such as lid 18 and TIM layer 35 of the 3D package of device 11, have an opening at the location of hole 3, so as to incorporate TCM 24 and HP 22 as shown in FIG. 1.

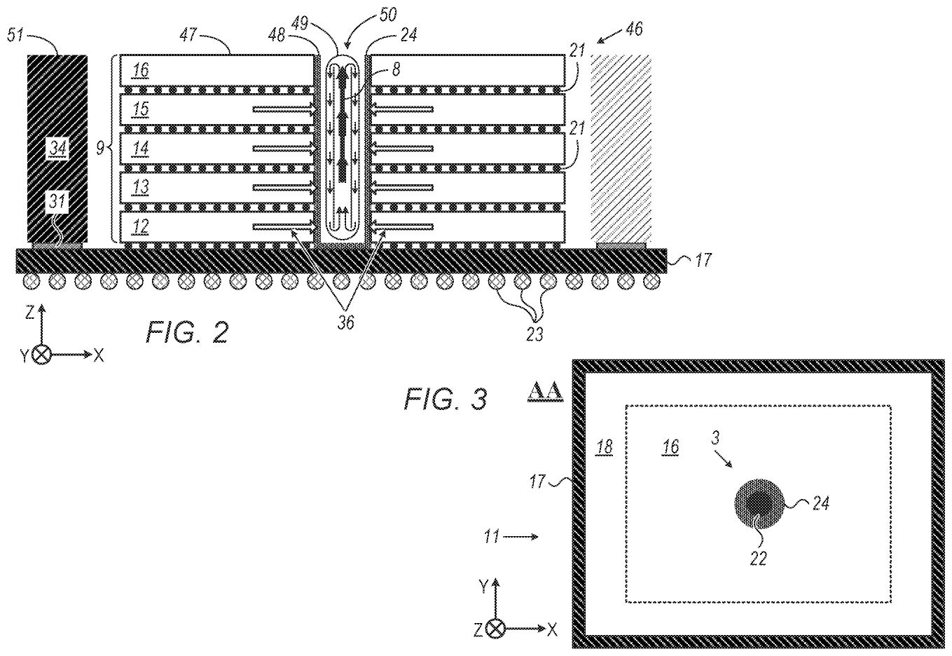

In some embodiments, the outer surfaces of hole 3, TCM 24 and HP 22 are typically flush with surface 4 of lid 18. Note that the production process of HP 22 and TCM 24 is described in detail in FIG. 10 below, and additional configurations of one or more HPs 22 that may be implemented in stack 9 and in the 3D package of dies 12-16, are shown and described in detail in FIGS. 2-9 below.

In other embodiments, instead of HP 22, stack 9 may comprise any other suitable type of heat pipe, which may be vertical (e.g., parallel to Z-axis), horizontal (e.g., parallel to the X-axis and/or Y-axis), or having any other suitable angle relative to the surface of substrate 17 and/or any of dies 12-16. Moreover, the heat pipe may have any suitable shape, other than a linear shape shown in FIG. 1.

In some embodiments, TCM 24 comprises any suitable type of thermally conductive epoxy, but may also comprise any suitable type of TCM other than epoxy. In one implementation, TCM 24 comprises EP30AN-1 epoxy supplied by Master bond Inc. (154 Hobart St, Hackensack, N.J. 07601), which is thermally conductive and electrically insulative. The EP30AN-1 epoxy has a relatively low coefficient of thermal expansion (CTE), (e.g., about 26×10⁻⁶/° C.), a relatively low viscosity (e.g., between about 5000 and 6000 cps at 75° F.) and sufficient flowability to be disposed over wall 3. In another implementation, TCM 24 comprises indium solder supplied by Indium Corporation (34 Robinson Rd, Clinton, N.Y. 13323), which is typically pre-plated between the outer wall of HP 22 (described in detail below) and the inner wall of hole 3. The indium solder: (i) has excellent thermal conductivity (e.g., about 86 W/m-k), (ii) malleable, and (iii) has a low melting point of about 157° C.

In other embodiments, in addition to TCM 24, or as an alternative to TCM 24, the inner wall of hole 3 may be coated with a plated layer of a suitable alloy of nickel and copper having a thickness between about 0.0025 mm and 0.025 mm.

In some embodiments, HP 22 is configured to dissipate heat from at least the subset of dies 12-16 in a direction 8 (e.g., along the Z-axis in case of a vertical heat pipe). In the present example, the heat produced in dies 12-15 of stack 9 dissipates in a direction 36 (e.g., along the X-axis) toward HP 22, and further dissipates away from stack 9 in direction 8. The heat produced in die 16 dissipates (i) through heat dissipation elements such as TIM layer 35 and lid 18 along the Z-axis (and optionally also along the X- and Y-axes thereof), and at the same time, (ii) in directions 36 and 8 through HP 22, as described above. Note that a section AA of device 11 will be used in a top view of the AA section in FIG. 3, for describing embodiments of the present disclosure.

Reference is now made to an inset 5 showing HP 22. In some embodiments, HP 22 comprises: (i) an inner wall 26 defining an inner channel 30 having a diameter between about 1 mm and 18 mm, (ii) an outer wall 25 surrounding inner wall 26, having a diameter between about 2 mm and 20 mm, and defining an outer channel 29 between inner wall 26 and outer wall 25. In some embodiments, at least one of inner wall 26 and outer wall 25 is made from copper or from copper plated with a preformed indium solder.

In the present example, inner channel 30 and outer channel 29 are concentric, and outer channel 25 has a width (e.g., along the X- and Y-axes) between about 1 mm and 19 mm. In other words, HP 22 has inner and outer concentric channels (also referred to herein as tubes) configured to flow a suitable fluid 33. In the present example, fluid 33 comprises any suitable type of cooling fluid, such as but not limited to water, ammonia, or any suitable type of solvent. Moreover, HP 22 has one or more openings in inner wall 26, which are configured for transferring fluid 33 between the inner and outer channels. In the present example, HP 22 has an opening 37 located at an upper section 19 of HP 22, and an opening 38 located at a lower section 20 of HP 22.

In alternative embodiments, device 11 comprises a trench (not shown) instead of hole 3, and the size and shape of the walls and channels may be altered in order correspond to the shape of the trench.

In the present example, section 20 is located in close proximity to dies 12-16 for dissipating heat therefrom while device 11 is being operated. Note that section 19 is farther from dies 12-16, and therefore, does not directly receive heat that may be produced by one or more of dies 12-16. In such embodiments, while device 11 is being operated, at least one of dies 12-16 produces heat, which is conducted in direction 36 toward HP 22, and the heat is transferred, via TCM 24, to fluid 33 located in lower section 20. Based on the location of sections 19 and 20, during and shortly after the operation of device 11, one or more of dies 12-16 are being operated and generate heat, and thereby, a temperature gradient is formed between a warmer section 20 and a colder section 19 of HP 22.

In some embodiments, a portion of fluid 33 that is located in section 20, is driven by the temperature gradient between sections 20 and 19, and therefore, flows along the Z-axis toward section 19. In the present example, a warmer portion of fluid 33 that is located in section 20, flows through opening 38 and being moved by the temperature gradient in a direction 27 through inner channel 30 toward section 19. Moreover, a colder portion of fluid 33 that is located in section 19, flows through opening 37 to outer channel 29 and in a direction 28 toward section 19. In such embodiments, in section 20 fluid 33 receives the heat produced by the dies, and the heat is transferred by fluid 33 to section 19 and dissipated, e.g., to lid 18 and to the environment (e.g., air) surrounding lid 18.

It is noted that in this configuration both lid 18 and TIM layer 35 are heat dissipation elements configured to dissipate heat from device 11 to the surrounding environment. Therefore, the flow of fluid 33 in directions 27 and 28 through channels 30 and 29, respectively, (and through openings 37 and 38,) results in the circulation of fluid 33, and consequently, the dissipation of heat from any of dies 12-16 in directions 36 and 8. It is known that in the heat transfer field between a hot source and a cold source, heat convection using fluid is typically substantially faster compared to heat conduction using a solid or a stationary fluid. In the present example, the heat transfer by HP 22 is between about 25 times and 300 times faster compared to that of a heat dissipation component having the same dimensions and filled with solid copper instead of the structure of HP 22 and fluid 33. For example, the thermal conductivity using solid copper is between about 350 W/m-K (watts per meter per kelvin) and 400 W/m-K, whereas the thermal conductivity using fluid 33 can be between about 10,000 W/m-K and 100,000 W/m-K depending, inter alia, on the flow rate and type of cooling fluid 33.

In alternative embodiments, fluid 33 may flow in opposite directions, e.g., in direction 27 through outer channel 29, and in direction 28 through inner channel 30. Moreover, HP 22 may have any suitable structural variation, for example, (i) channels 29 and 30 may be arranged in a non-concentric geometry, (ii) HP 22 may comprise three or more channel, at least two of the channels may be concentric or non-concentric with one another, and (iii) any other suitable configuration of HP 22.

Additionally, or alternatively, device 11 may comprise at least one HP 22 that may have any other suitable structure, such as one or more tubes arranged in one or more serpentines and/or spirals, or in any other suitable geometrical structure that enables (e.g., increases) the dissipation of the heat produced by any of dies 12-16, away from device 11.

FIG. 2 is a schematic, sectional view of an electronic device 46, in accordance with another embodiment that is described herein. Electronic device 46 is also referred to herein as device 46, for brevity, and has a lidless package as will be described in detail below.

In some embodiments, device 46 comprises dies 12-16, bumps 21, substrate 17 and solder balls 23 typically arranged in the same structure described in detail in FIG. 1 above. In some embodiments, instead of lid 18, device 46 comprises a stiffener ring, referred to herein as a stiffener 34, which is formed over adhesive layer 31 and substrate 17, and is made of a heat conducting material such as but not limited to nickel-plated copper or stainless steel. In the present example, adhesive layer 31 has a thickness between about 50 μm and 200 μm, and is configured to bond stiffener 34 and substrate 17 together.

In some embodiments, device 46 comprises one or more HPs 50, at least one of HPs 50 comprises a VHP whose longitudinal axis is approximately orthogonal to substrate 17, as described in detail in HP 22 of FIG. 1 above. Each of HPs 50 is traversing dies 12-16, but is not traversing a lid that does not exist in device 46. Thus, each HP 50 is shorter, along the Z-axis, compared to HP 22 of device 11. Yet, in the present example, HP 50 has the same structure of the inner and outer walls and channels of HP 22 described in FIG. 1 above. Moreover, HP 50 typically contains fluid 33, which is configured to flow through the inner and outer channels, as described in FIG. 1 above.

In some embodiments, outer surfaces 48, 49 and 51 of TCM 24, HP 50 and stiffener 34, respectively, are typically flush with one another and with an outer surface 47 of die 16. In other embodiments, TIM layer 35, or any other suitable type of TIM layer, may be formed over surfaces 47 and 51. In such embodiments, surfaces 48 and 49 may be either: (i) flush with the upper surface of the TIM layer, or (ii) remain flush with surface 47 and also be coated by the same TIM layer. It is noted that in both configurations, the heat produced by one or more dies 12-15, and at least part of the heat produced by die 16, are dissipated in directions 36 and 8, as described in FIG. 1 above.

FIG. 3 is a schematic, a top view of the AA section of electronic device 11 shown in FIG. 1 above, in accordance with an embodiment that is described herein.

In some embodiments, hole 3 is positioned at the center of device 11, and configured to dissipate heat from at least one of, and typically all dies 12-16 along the Z-axis, as described in detail in FIG. 1 above. The top view of the AA section shows HP 22 and TCM 24 formed within hole 3, die 16 whose top view is indicative of the footprint of dies 12-16 on substrate 17, and the sides of lid 18 surrounding dies 12-16, as described in FIG. 1 above.

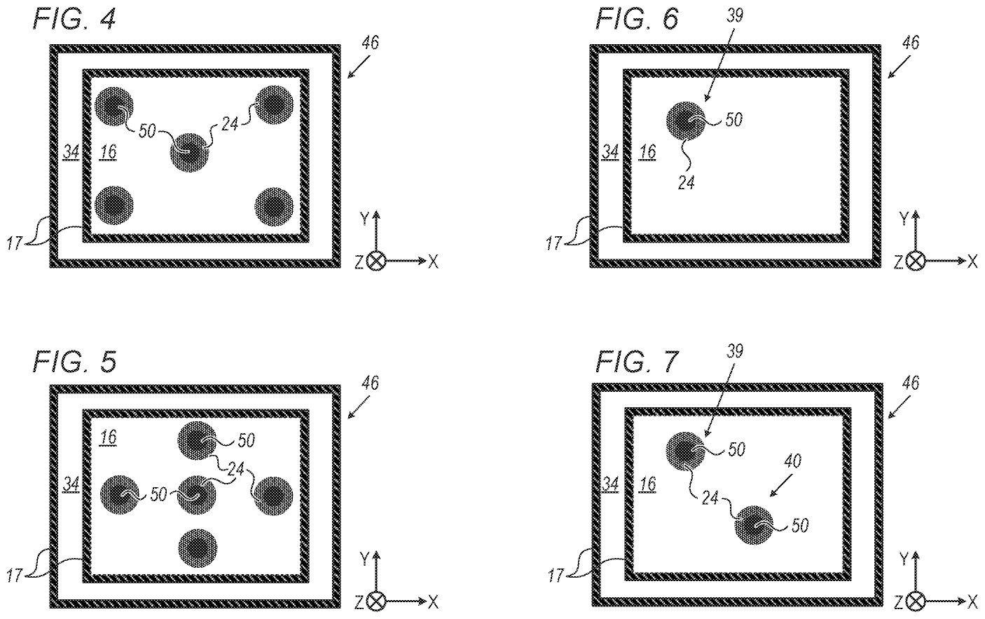

FIGS. 4-7 are schematic, top views of electronic device 46, in accordance with embodiments that are described herein.

Reference is now made to FIG. 4. In some embodiments, device 46 comprises four HPs 50 and TCMs 24 arranged approximately at the corners of the stacked dies 12-16, and one HP 50 and TCM 24 are located at the center of the stacked dies 12-16. It is noted for FIGS. 4-7 that each hole containing the respective HP 50 and TCM 24 is defined as a keep-out zone in which no functional electronic component may be produced in any of dies 12-16, as described in detail in FIG. 1 above. In this configuration, the computing functionality (e.g., processing speed and/or memory capacity) of device 46 may be reduced (e.g., compared to device 11 of FIG. 1 above) due to the large number of keep-out zones. However, due to the larger number of HPs, heat dissipation from device 46 is typically faster compared to that of device 11.

Reference is now made to FIG. 5. In some embodiments, device 46 comprises four HPs 50 and TCM 24 that are arranged approximately at the centers of the respective sides of the stacked dies 12-16, and one HP 50 and TCM 24 are located at the center of the stacked dies 12-16. The configuration difference between FIGS. 4 and 5 may be required due to a different distribution of the heat generated by dies 12-16, and the arrangement of HPs 50 is adapted in order to improve the heat dissipation from the stack of dies 12-16.

Reference is now made to FIGS. 6 and 7. In some cases, the designers of device 46 are aware of hot spots, such as hot spots 39 and 40 in at least one of dies 12-16. In the context of the present disclosure and in the claims, the term hot spot (or hotspot) refers to a region in one or more dies 12-16 having a temperature that exceeds a temperature threshold during operation of the respective dies. In some embodiments, the holes having HPs 50 and TCMs 24 of device 46 are located in close proximity to hot pots 39 and 40, e.g., at a localized high-density of power on the surface area of the respective dies. In the example of FIG. 6, device 46 comprises a single HP 50 and TCM 24 located in close proximity to hot spot 39, and in the example of FIG. 7, device 46 comprises two sets of HPs 50 and TCMs 24 located in close proximity to hot spots 39 and 40, respectively.

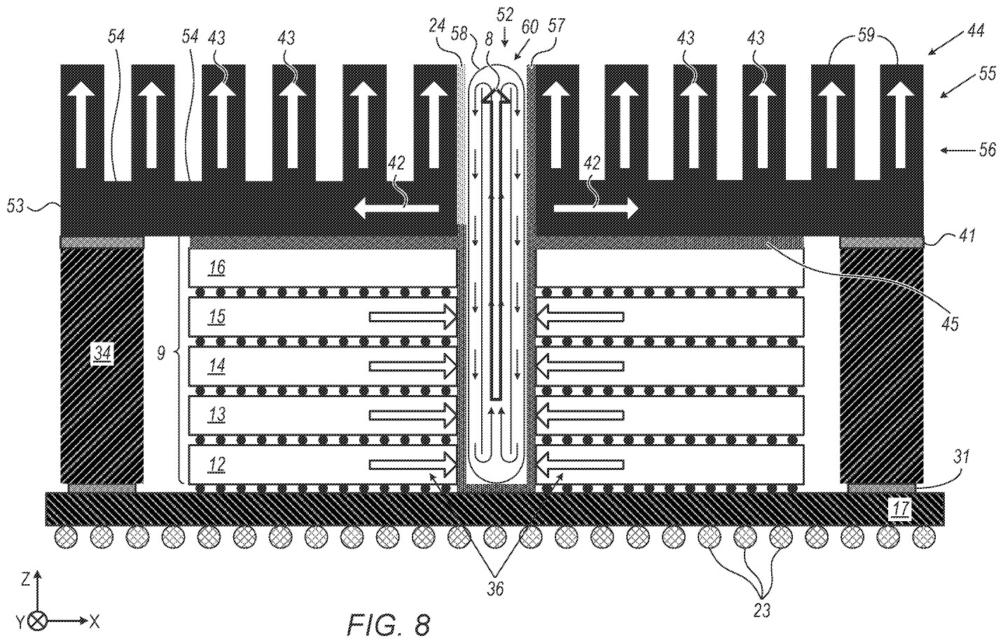

FIG. 8 is a schematic, sectional view of an electronic device 55, in accordance with another embodiment that is described herein. Electronic device 55 is also referred to herein as a device 55, for brevity.

In some embodiments, device 55 comprises dies 12-16, bumps 21, substrate 17 and solder balls 23 (or other suitable terminals, such as pads or pins of LGA and PGA configurations) typically arranged in the same structure described in detail in FIG. 1 above. In some embodiments, device 55 comprises a stiffener 34, whose structure and properties are similar to the stiffener of FIG. 2 above. Stiffener 34 is formed over adhesive layer 31 and substrate 17, and is made of a heat conducting material such as but not limited to nickel-plated copper or stainless steel. In the present example, adhesive layer 31 that is disposed between stiffener 34 and substrate 17, has a thickness between about 50 μm and 200 μm, and is configured to bond stiffener 34 and substrate 17 together.

In some embodiments, device 55 comprises a TIM layer 45, which comprises any suitable material, such as for example a thermal conductive gel product X23-7762 supplied by Shin-Etsu MicroSi Inc. (10028 S. 51st Street Phoenix, Ariz. 85044), and having a thickness between about 20 μm and 150 μm.

In some embodiments, device 55 comprises a heat dissipation element, in the present example, a heat sink (HS) 44, which is configured to dissipate the heat produced by at least one of dies 12-16 and transferred by at least a HP 52 described below. In some embodiments, HS 44 comprises a base plate 53 and a plurality of ribs 56 extended from a surface 54 of base plate 53. The heat produced by any of dies 12-16 is conducted: (i) in directions 36 and 8, as described in FIGS. 1 and 2 above, and (ii) in directions 42 and 43 through base plate 53 and ribs 56, respectively.

In some embodiments, HS 44 is disposed over TIM layer 45 and over an adhesive layer 41 having a thickness between about 100 μm and 500 μm, is disposed between stiffener 34 and HS 44. Adhesive layer 41 may comprise a substance similar to that to adhesive layer 31 described in FIGS. 1 and 2 above, or may comprise any other suitable type of adhesive substance, such as SYLGARD™ 577 Primerless silicone adhesive product, supplied by Dow Chemical Company (2211 H.H. Dow Way Midland, Mich. 48674), which is configured to enhance heat sink bonding strength.

In some embodiments, device 55 comprises one or more holes 60 traversing at least two of (and typically all) dies 12-16, and also traversing TIM layer 45 and HS 44. Each hole 60 contains a TCM 24 and a HP 52. In the present example, HP 52 has the same structure of the inner and outer walls and channels of HP 22 described of FIG. 1 above. Moreover, HP 52 is configured to contain and flow fluid 33 through the inner and outer channels, as described with reference to FIG. 1 above. It is noted that the size of hole 60, TCM 24 and HP 52 along the Z-axis is typically larger compared to that of HP 22 of FIG. 1 above, in accordance with embodiments described herein.

In some embodiments, an outer surface 58 of the outer channel of HP 52 is typically flush with an outer surface 57 of TCM 24 and with a surface 59 of ribs 56.

In other embodiments, the opening of hole 60 and outer surfaces 57 and 58 may be flush with surface 54 of base plate 53. In yet other embodiments, the opening of hole 60 and outer surfaces 57 and 58 may be located at any suitable level (along the Z-axis) between surfaces 59 and 54 of HS 44.

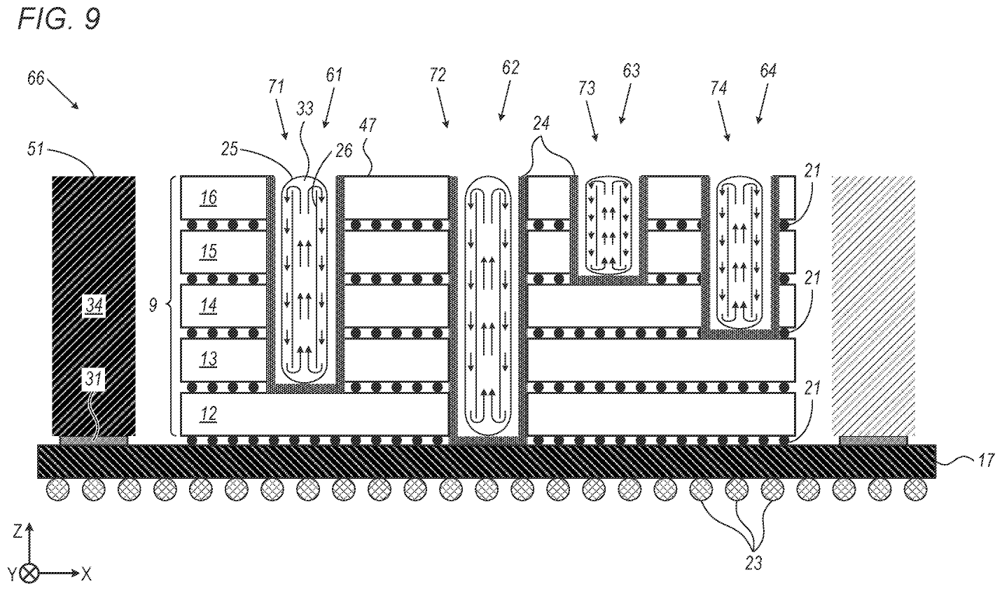

FIG. 9 is a schematic, sectional view of an electronic device 66, in accordance with another embodiment that is described herein. Electronic device 66 is also referred to herein as a device 66, for brevity, and has a lidless package as described, for example, in the example of FIG. 2 above.

In some embodiments, device 66 comprises dies 12-16, bumps 21, substrate 17, solder balls 23, stiffener 34, and adhesive layer 31, all of them are arranged in a similar configuration to that of device 46 of FIG. 2 above.

In some cases, different amount of heat may be generated during the operation of dies 12-16. In the present example, dies 15 and 16 generate the largest amount of heat, and die 12 generates the least amount of heat among dies 12-16. Additionally, or alternatively, each die among dies 12-16 may have a different number of hot spots.

In some embodiments, the number of HPs, and the depth and location of each HP are configured according to the number and locations of hot spot in each of dies 12-16. In the present example, device 66 comprises HPs 61, 62, 63 and 64 formed in holes 71, 72, 73 and 74, respectively. In the present example, hole 71 traverses dies 13-16, hole 72 traverses dies 12-16, hole 73 traverses dies 15 and 16, and hole 74 traverses dies 14-16. In such embodiments, each of HPs 61, 62, 63 and 64 has outer and inner channels, which are defined by outer wall 25 and inner wall 26, and are configured to contain fluid 33 and to flow fluid 33 for dissipating the heat generated by any of dies 12-16, as described in detail in FIGS. 1 and 2 above.

In some embodiments, each pair of hole and HP among holes 71, 72, 73 and 74, and HPs 61, 62, 63 and 64, has a different size along the Z-axis. Additionally, or alternatively, the size (e.g., diameter) of holes 71, 72, 73 and 74 may differ from one another depending on the heat dissipation requirements of a given application of device 66 or any other suitable devices (e.g., devices 11, 46, and 55) having multiple holes and HPs. In other words, the holes and HPs formed in the stack of dies may be similar or different along the XY plane and/or along the Z-axis of the device.

In some embodiments, during the operation of dies 12-16, each HP is configured to dissipate heat generated by at least a respective subset of dies 12-16. In the present example: (i) HPs 61-64 dissipate the heat generated by dies 15 and 16, (ii) HPs 61, 62 and 64 dissipate the heat generated by die 14, (iii) HPs 61, and 62 dissipate the heat generated by dies 13, and (iv) HP 62 dissipates the heat generated by die 12. It is noted that using this arrangement enables customized and differential heat transfer from each die among the stacked dies 12-16 of device 66. For example, dies 12 and 13 may comprise memory devices, and during operation dies 12 generates less heat compared to the heat generated by die 13. Therefore, less real estate of keep-out zone is required to dissipate the heat from die 12, and consequently, more real estate may be used to increase the memory capacity of die 12. In other words, heat pipes inserted at different levels of a stack of dies, provides the packaging designer with the flexibility to have customized and differential heat dissipation from each die of the package.

It is noted that the particular configurations of devices 11, 46, 55 and 66 are provided by way of example, in order to illustrate certain problems that are addressed by embodiments of the present invention and to demonstrate the application of these embodiments in enhancing the performance of such devices having multiple dies stacked in a suitable type of a three-dimensional (3D) package. Embodiments of the present invention, however, are by no means limited to this specific sort of example devices and 3D packages, and the principles described herein may similarly be applied to other sorts of multi-die packaging techniques and respective devices. For example, at least one of the HPs of devices 11, 46, 55 and 66 can come at any shape and angle, e.g., in order to avoid passing a section of a HP through an area defined to be functional in a given die of the stack. In one implementation, the HP may have at least two sections traversing two different regions in the XY plane of at least two of the stacked dies, respectively.

FIG. 10 is a flow chart that schematically illustrates a method for producing electronic device 66, in accordance with an embodiment that is described herein.

The method begins at a die stacking operation 100 with disposing stack 9 of dies 12-16 and bumps 21 over substrate 17, as described in detail in FIG. 1 above.

At a hole formation operation 102, holes 71-74 are formed using a laser drilling process, or a suitable dry etching and/or wet etching process. For example, (i) QUASAR 532-95 tool for TSV drilling using UV laser supplied by Spectra-Physics, A Newport Company (3635 Peterson Way, Santa Clara, Calif. 95054), (ii) a Bosch process for Deep reactive ion etching (RIE) carried out using a system supplied by SAMCO (2302 Walsh Ave, Santa Clara, Calif. 95051), and (iii) mechanical drilling in the silicon of wafers 12-16 using Micro PCD drills supplied by Telcon Diamond cutting tools (2 Hamal St PO Box 1063, Afula 1811001, Israel), or using any other suitable tools and processes. In the example of device 66, holes 71-74 have different size along the Z-axis, and thereby, each of the holes traverses different dies among dies 12-16, as described in FIG. 9 above.

In some embodiments, the design of dies 12-16 allocates one or more keep-out zones that do not have any functional electronic component, such as transistors and/or memory cells, as described for example in FIGS. 1, 4 and 6-7 above.

In some embodiments, the number of holes intended to contain HPs, the location of the holes, and the diameter of each hole can be determined based on the power dissipation requirement for the respective application of device 66. In an embodiment, the laser drilling and/or etching process may be carried out after stacking dies 12-16 in stack 9, as described above. In an alternative 28 embodiment, holes 71-74 may be produced before stacking dies 12-16 using a middle-end-of-line (MEOL) process sequence. In this embodiment, holes 71-74 may be produced during the formation of the TSVs in each of dies 12-16, followed by (i) the formation of micro bump pads (MBPs), (ii) wafer thinning, (iii) exposure of the holes, and (iv) deposition and patterning of passivation and redistribution layers. It is noted that the formation of bumps 21 is carried out on in wafer level, but not in the keep-out zones intended to receive the heat pipes.

In some embodiments, after conducting the MEOL process, an etching process is carried out at the back side of the wafers comprising dies 12-16, so as to finalize the formation of holes 71-74.

In some embodiments, after the formation of holes 71-74, a temporary jig (shown and described in FIG. 11 below) is placed over stack 9 of dies 12-16 in order to enable a reflow process while maintaining the shape and required properties of holes 71-74.

At a heat pipe formation operation 104 that concludes the process, the temporary jig is removed after the reflow process. Subsequently, (i) TCM 24 is formed by disposing the epoxy layer (described in FIG. 1 above) over the walls of holes 71-74, and (ii) disposing HPs 61-64 in holes 71-74, respectively, in order to enable the dissipation of heat from dies 12-16, as described in FIG. 9 above.

In some embodiments, HPs 61-64 are formed such that the outer surface of outer wall 25 is approximately flush with surface 47 of die 16. Moreover, it is noted that the different size of holes 71-74 along the Z-axis enables the differential heat transfer from each die among the stacked dies 12-16, as described in detail in FIG. 9 above.

In some embodiments, additional process steps may be carried out after concluding the formation of stack 9 and HPs 61-64. For example, mounting stack 9 over substrate 17 and placing and bonding stiffener 34 over substrate 17 using adhesive layer 31.

The operations of the method of FIG. 10 are simplified for the sake of conceptual clarity and are provided by way of example. Embodiments of the present disclosure, however, are by no means limited to this specific sort of fabrication technique and optional process sequences, and the principles described herein may similarly be applied to other sorts of methods used for producing an electronic device comprising a stack of dies and vertical heat pipes.

FIG. 11 is a schematic, sectional view of a jig 80 used for producing HPs 61-64 of electronic device 66, in accordance with an embodiment that is described herein.

In some embodiments, jig 80 comprises a temporary jig having a base plate 85 and multiple ribs extended from base plate 85. In the present example, jig 80 comprises ribs 81, 82, 83 and 84 shaped to fill holes 71, 72, 73, and 74, respectively. In such embodiments, after the formation of holes 71-74, base plate 85 is placed over surface 47 of die 16, such that ribs 81, 82, 83 and 84 snugly fit in holes 71, 72, 73, and 74, respectively. In other words, ribs 81-84 are used as placeholders for the intended positions of HPs 61-64, respectively.

This particular configuration of jig 80 is shown by way of example, in order to illustrate certain problems that are addressed by embodiments of the present invention and to demonstrate the application of these embodiments in improving the production flow and enhancing the performance of an electronic device comprising a three-dimensional package of stacked dies, such as device 66. Embodiments of the present invention, however, are by no means limited to this specific sort of example process flow and electronic device, and the principles described herein may similarly be applied to other sorts of production processes, and other sorts of electronic devices, such as but not limited to devices 11, 46 and 55 of the present disclosure.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a substrate; and
a stack of dies stacked on the substrate, the stack comprising:
multiple dies stacked on one another, the multiple dies comprising electronic components and interconnections; and
one or more heat pipes (HPs), which are traversing at least a subset of the dies at a right angle relative to the substrate, at least one of the HPs being configured to dissipate heat generated by operation of the electronic components away from at least the subset of the dies.

2. The electronic device according to claim 1, wherein at least one of the HPs contains a fluid, at least the one of the HPs being configured to move the fluid within the HP for dissipating the heat.

3. The electronic device according to claim 2, wherein the HP comprises: (i) an inner wall defining a first channel, (ii) an outer wall surrounding the inner wall and defining a second channel between the inner wall and outer wall, and (iii) one or more first openings in the inner wall for transferring the fluid between the first channel and second channel.

4. The electronic device according to claim 3, wherein the multiple dies comprise (i) a first die being an outer die of the stack, and (ii) a second die disposed on the substrate, wherein at least one of the HPs traverses at least the first die.

5. The electronic device according to claim 4, wherein the stack comprises a third die disposed between the first die and the second die, wherein the HPs comprise: (i) a first HP traversing the first die and the third die but not traversing the second die, and (ii) a second HP traversing the first die, the third die and the second die.

6. The electronic device according to claim 4, wherein the first die has a first surface being an outer surface of the stack of dies, and comprising a heat dissipation element disposed over the first surface and having a second surface opposite the first surface of the first die, the heat dissipation element being configured to dissipate the heat from at least one of the dies.

7. The electronic device according to claim 6, wherein the heat dissipation element has a—second opening, wherein at least one of the HPs is configured to traverse at least part of the second opening along the heat dissipation element.

8. The electronic device according to claim 7, wherein a third surface, of the outer wall of at least one of the HPs, is flush with the second surface of the heat dissipation element.

9. The electronic device according to claim 1, comprising (i) a hole traversing at least the subset of the dies, the hole being configured to contain a given HP of the HPs, and (ii) a layer formed between the given HP and a wall of the hole, the layer comprises thermally conductive material (TCM) configured to transfer the heat between the subset of the dies and the given HP.

10. The electronic device according to claim 1, wherein at least one of the HPs being disposed at a region identified as a hot spot in at least one of the dies.

11. A method for producing an electronic device, the method comprising:
disposing on a substrate a stack of dies, the stack comprising multiple dies stacked on one another, the multiple dies comprising electronic components and interconnections; and
fabricating in the stack one or more heat pipes (HPs), which are traversing at least a subset of the dies at a right angle relative to the substrate, at least one of the HPs used for dissipating heat, which is generated by operation of the electronic components, away from at least the subset of the dies.

12. The method according to claim 11, wherein at least one of the HPs contains a fluid, wherein fabricating the one or more HPs comprises fabricating at least the one of the HPs for moving the fluid within the HP for dissipating the heat.

13. The method according to claim 12, wherein fabricating the HP comprises fabricating: (i) an inner wall defining a first channel, (ii) an outer wall surrounding the inner wall and defining a second channel between the inner wall and outer wall, and (iii) one or more first openings in the inner wall for transferring the fluid between the first channel and second channel.

14. The method according to claim 13, wherein disposing the stack comprises disposing: (i) a first die being an outer die of the stack, and (ii) a second die on the substrate, wherein at least one of the HPs traverses at least the first die.

15. The method according to claim 14, wherein disposing the stack comprises disposing a third die between the first die and the second die, wherein fabricating the one or more HPs comprise fabricating: (i) a first HP traversing the first die and the third die but not traversing the second die, and (ii) a second HP traversing the first die, the third die and the second die.

16. The method according to claim 14, wherein the first die has a first surface being an outer surface of the stack of dies, and comprising disposing over the first surface, a heat dissipation element having a second surface opposite the first surface of the first die, the heat dissipation element being disposed for dissipating the heat from at least one of the dies.

17. The method according to claim 16, wherein the heat dissipation element has a second opening, wherein fabricating the one or more HPs comprises forming at least one of the HPs to traverse at least part of the second opening along the heat dissipation element.

18. The method according to claim 17, wherein disposing the stack comprises disposing a third surface of the outer wall of at least one of the HPs, being flush with the second surface of the heat dissipation element.

19. The method according to claim 11, wherein fabricating the one or more HPs comprises forming: (i) a hole traversing at least the subset of the dies, the hole is formed for containing a given HP of the HPs, and (ii) a layer between the given HP and a wall of the hole, the layer comprises thermally conductive material (TCM) for transferring the heat between the subset of the dies and the given HP.

20. The method according to claim 11, wherein fabricating the one or more HPs comprises disposing at least one of the HPs at a region identified as a hot spot in at least one of the dies.
